(19) United States
(12) Patent Application Publication
(10) Pub. No.: US 2011/0300310 A1
(43) Pub. Date: Dec. 8, 2011

(54) Method and Device for Coating Functional Surfaces

(75) Inventors: Johann SCHNAGL, Fuerstenfeldbruck (DE); Serge Kursawe, Uttenreuth (DE); Hans-Joachim Scheibe, Dresden (DE); Volker Weihnacht, Dresden (DE)

(73) Assignees: Fraunhofer Gesellschaft zur Foerderung der Angewandten Forschung E.V., Muenchen (DE); Bayerische Motoren Werke Aktiengesellschaft, Muenchen (DE)

(21) Appl. No.: 13/178,157

(22) Filed: Jul. 7, 2011

Related U.S. Application Data
(63) Continuation of application No. PCT/EP2009/008914, filed on Dec. 12, 2009.

(30) Foreign Application Priority Data
Jan. 9, 2009 (DE) 10 2009 004 158.3

(51) Int. Cl. C23C 16/48; C23C 16/04; C23C 16/50

(52) U.S. Cl. 427/569; 427/595; 118/624; 118/623

(57) ABSTRACT

A method and system for coating the functional surfaces of symmetrically serrated components, in particular the tooth flanks of gears, includes a coating source emitting coating material in the form of electrically charged particles in the direction of a revolving component. A high-quality functional surface coating of the component is achieved in that a shield is arranged in the beam path between the component and the coating source transversely to the irradiation direction, which shields the component from the coating beam in a contour area with a functional surface orientation inclined flatly with respect to the irradiation direction.

### CROSS-REFERENCE TO RELATED APPLICATIONS

This application is a continuation of PCT International Application No. PCT/EP2009/008914, filed Dec. 12, 2009, which claims priority under 35 U.S.C. §119 from German Patent Application No. DE 10 2009 004 158.3, filed Jan. 9, 2009, the entire disclosures of which are herein expressly incorporated by reference.

### BACKGROUND AND SUMMARY OF THE INVENTION

The invention relates to a method and to a device for coating the functional surfaces of symmetrically serrated components, in particular the tooth flanks of gears, having a coating source emitting the coating material in the form of electrically charged particles in the direction of the component.

It is known to coat the tooth flanks of toothed wheels for improving the running characteristics by way of a gaseous deposition in such a manner that a plasma, which is produced by a coating source, for example, on a graphite base, and is accelerated in an electric or magnetic field, is, for example, emitted at a high speed onto the tooth flanks and is embedded there in the tooth flank areas that are close to the edge. In the tooth flank areas, the graphitic plasma particles are converted into an extremely hard diamond-type coating. In addition to the degree of ionization and the energy of the plasma particles, their impact angle on the component surface is also decisive for the coating quality. However, during the revolving movement, the orientation of the tooth flanks with respect to the irradiation direction will change, and with an increasingly smaller angle of impact, the penetration depth of the plasma particles into the surface will be reduced. This results in the layer quality on the tooth flanks not being sufficient for ensuring a durably high-quality tooth flank coating.

In contrast to the above, it is an object of the invention to further develop the method and the device of the above-mentioned type such that a qualitatively high-value functional surface coating of the component and, in particular, of the tooth flanks of the gear is achieved.

According to the invention, this and other objects are achieved by a method and system for coating the functional surfaces of symmetrically serrated components, in particular the tooth flanks of gears, by use of a coating source emitting coating material in the form of electrically charged particles in the direction of the component and revolving relative to the component. During the coating process, the component is shielded from the coating beam in a contour area with a functional surface orientation inclined flatly with respect to the irradiation direction by a shield arranged between the component and the coating source transversely to the irradiation direction.

According to the invention, as a result of a constructively simple shielding of the component, the critical contour area, in which the functional surfaces of the component are set at a flat angle with respect to the irradiation direction, is shielded. As a result, an incidence-caused insufficient layer adhesion and quality are effectively prevented. The result is a coating with excellent tribolic characteristics, as required, particularly for highly-stressed toothed gears, for example, in motor vehicle transmissions, which coating is integrally connected with the component.

In a particularly preferred further development of the invention, the component and the coating source are driven in a revolving manner intermittently relative to one another or non-uniformly with longer dwell times in the rotating position of the functional surfaces set steeply with respect to the irradiation direction, so that the main part of the coating material impacts on the functional surface in an angular area that is optimal with respect to the layer adhesion and layer hardness.

Within the scope of the invention and for saving coating material and coating time, the functional surfaces can easily also be coated on only one side of the component teeth. Thus, at the toothed gears, only the tooth flanks that are more stressed in the running direction are coated in a simple manner such that the component is completely shielded in a half-sided manner by the shield beyond one boundary of the contour area.

As known per se, an ion beam or a plasma beam, which, for the purpose of a better guidance, is additionally deflected by way of an electric and/or magnetic field, is preferably used as the coating material. In this case, the field is particularly preferably combined with the shield such that the coating beam is focused such that a portion of the coating particles otherwise intercepted by the shield is deposited on the functional surface in a manner that is effective with respect to the coating while increasing the coating intensity, and the coating rate is thereby raised significantly.

In a particularly preferred variant of the invention, in the problematic case of a bevel gear coating with spirally extending tooth flanks, the flank area that is exposed to the impact coating at a sufficiently steep angle can be clearly enlarged in a simple manner in that the bevel gear axis is diagonally inclined in a tilted position fixed with respect to the irradiation direction.

Other objects, advantages and novel features of the present invention will become apparent from the following detailed description of one or more preferred embodiments when considered in conjunction with the accompanying drawings.

### BRIEF DESCRIPTION OF THE DRAWINGS

FIGS. 1a, b are simplified schematic views of a tooth flank coating of a gear according to a first embodiment of the invention;

FIG. 2 is a simplified schematic view of a toothed gear coating corresponding to FIG. 1 at a reduced scale in a second embodiment of the invention;

FIG. 3 is a simplified schematic view of a tooth flank coating with a device for focusing the coating beam combined with the shield; and

FIG. 4 is a simplified schematic view of a further variant of the invention for the tooth flank coating of a bevel gear.

### DETAILED DESCRIPTION OF THE DRAWINGS

The coating system illustrated in the figures is used for coating the tooth flanks 3 of toothed gears 1. The coating system contains a coating source 2 which emits in the direction of the toothed gear a coating beam in the form of an ionized plasma current. The ionized plasma current is illustrated in the figures in an idealized manner as a parallelized coating beam but, in reality, is significantly more diffuse. In a magnetic and/or electric field, for example, by applying an electric voltage to the toothed gear 1, the plasma particles are accelerated to such an extent that they impact on the tooth flanks 3 with a high kinetic energy and form a firmly adhering hard coating there.

During the coating process, the toothed gear 1 is rotated about the toothed gear axis, such that all tooth flanks 3 successively arrive in the coating beam of the coating source 2. However, in the process, the orientation of the tooth flanks 3 with respect to the irradiation direction changes and thereby also the impact angle of the plasma particles on the tooth flank 3. In a contour area of the toothed gear 1 with a tooth flank orientation that is “flat” with respect to the irradiation direction, the impact angle of the plasma particles becomes so small that a sufficient layer adhesion and layer quality is no longer achieved.

A so-called “flat” tooth flank orientation means an inclination of the tooth flanks 3 with respect to the direction of the impacting plasma current wherein, upon impact with on the tooth flanks 3, the plasma particles are either reflected or form a coating that does not meet the quality requirements with respect to the layer adhesion and layer hardness. This critical inclination angle is also a function of the remaining process parameters and, in the illustrated embodiments, is situated in the range between approximately 10 and 20°.

In this contour area, the toothed gear is shaded from the plasma current in a constructively simple manner according to the invention, specifically by a shield 4 arranged between the toothed gear 1 and the coating source 2 transversely to the irradiation direction.

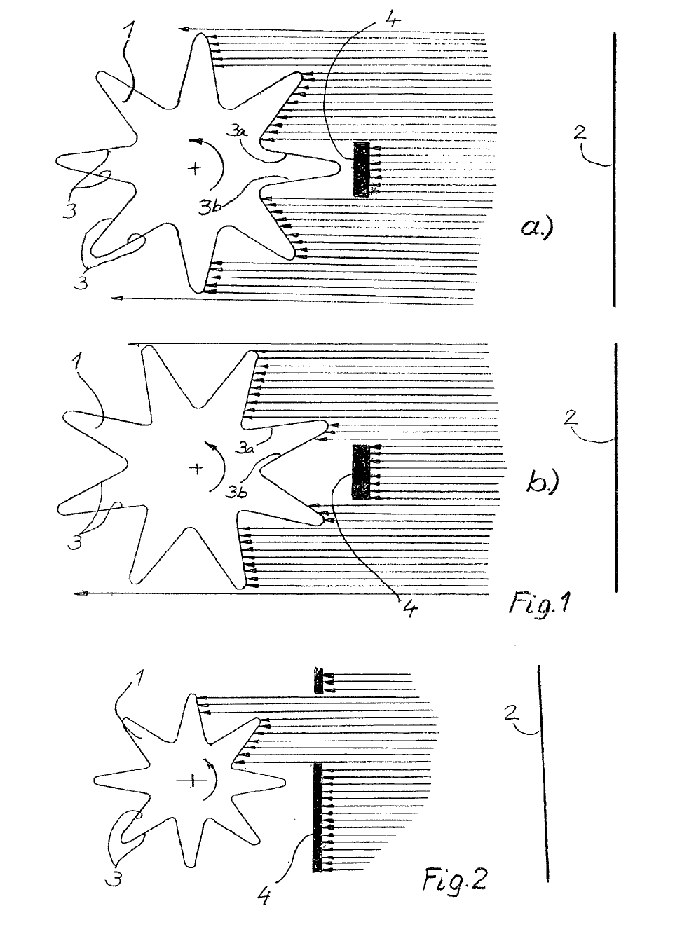

In the embodiment according to FIG. 1, specifically in the rotational position illustrated in FIG. 1a, the two tooth flanks 3a and 3b are, at that particular moment, in the critical contour area with a surface orientation inclined flatly with respect to the irradiation direction. Accordingly, they are shielded from the coating beam by the shield 4. When the toothed gear 1 continues to rotate (FIG. 1b), the forward tooth flank 3a arrives in a rotational position shaded by the tooth tip, while the tooth flank 3b that is rearward in the rotating direction moves into the transmission direction of the shield 4 and is now oriented at a sufficiently large angle of inclination with respect to the irradiation direction. Upon further rotation of the toothed gear 1, the impact angle of the plasma current on the tooth flank 3b becomes increasingly steeper and reaches the coating-optimal impact angle range of up to 90°. In this range, the rotational movement of the toothed gear 1 is slowed down or stopped, and it is thereby ensured that the main portion of the coating material is deposited in a coating-optimal manner. During the revolving of the toothed gear 1, all tooth flanks 3 are successively coated in this manner.

The coating system illustrated in FIG. 2, in which the components corresponding to the first embodiment are marked by the same reference symbols, differs from the first embodiment mainly in that the shield 4 is lengthened on one side, so that it completely shades half of the toothed gear. As a result, a one-sided tooth flank coating is achieved, as preferred for toothed gears which, in the operating condition, are predominantly or exclusively stressed only at one and the same tooth flank of each pair of flanks.

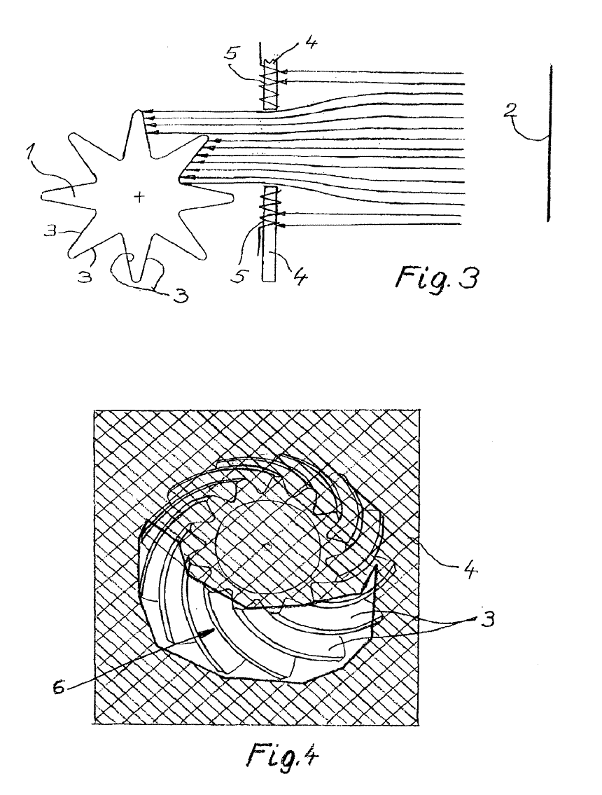

In the case of the embodiment illustrated in FIG. 3, the shield 4 is combined with an electric or magnetic field guidance 5. Such guidance causes a focusing of the plasma current such that a portion of the plasma current which would otherwise be intercepted by the shield 4, while the coating beam cross-section is narrowed on the path via the shield transmission, is also deposited in a coating-effective manner. As a result, the coating intensity of the impacting plasma current and, correspondingly also the time-related coating rate, are significantly increased.

FIG. 4 illustrates the plasma coating of a bevel gear 6 with spirally extending tooth flanks 3. In this case, merely by a tilting of the bevel gear axis from a position perpendicular to the irradiation direction into an inclined position sloped thereto, with the tapered bevel gear end in the direction of the coating source, the surface part of the tooth flanks 3 on which the plasma particles impact on the tooth flanks 3 at a sufficiently large impact angle, is clearly enlarged, while the remaining flank areas with a flat surface orientation are shaded by the shield 4 illustrated in FIG. 4 in a cross-hatched manner. In the perspective view of FIG. 4, the coating source is situated above the plane of the drawing and is not shown, and the irradiation direction is slightly inclined with respect to the viewing direction.

Naturally, the functional surfaces of other central-symmetrically serrated components, for example, drills or milling cutters, can also be coated in an analogous manner within the scope of the invention.

The foregoing disclosure has been set forth merely to illustrate the invention and is not intended to be limiting. Since modifications of the disclosed embodiments incorporating the spirit and substance of the invention may occur to persons skilled in the art, the invention should be construed to include everything within the scope of the appended claims and equivalents thereof.

What is claimed is:

1. A method for coating functional surfaces of symmetrically serrated components, the method comprising the acts of:
emitting a coating beam of coating material as electrically charged particles from a coating source in an irradiation direction of a component;
rotating at least one of the component and coating beam relative to one another; and
shielding a contour area of the component from the coating beam, the contour area having a functional surface orientation that is inclined flatly with respect to the irradiation direction using a shield arranged transversely to the irradiation direction between the component and the coating source.

2. The method according to claim 1, wherein the component is a gear having toothed flanks.

3. The method according to claim 1, wherein relative rotation between the component and the coating source about an axis of the component is non-uniform with longer dwell times occurring in a rotational position of the functional surfaces set steeply with respect to the irradiation direction.

4. The method according to claim 1, wherein the shielding act shades in a half-sided manner beyond one boundary of the contour area of the component, whereby one-sided functional surface coating occurs.

5. The method according to claim 3, wherein the shielding act shades in a half-sided manner beyond one boundary of the contour area of the component, whereby one-sided functional surface coating occurs.

6. The method according to claim 1, wherein the coating source emits one of an ion and plasma current.

7. The method according to claim 1, further comprising the act of:
deflecting the coating beam via at least one of a magnetic and electric field.

8. The method according to claim 7, further comprising the act of:
focusing the coating beam via the at least one of the magnetic and electric field.

9. The method according to claim 1, wherein the component is a bevel gear, and further comprising the act of:
rotating the bevel gear about a bevel gear axis during coating, the bevel gear axis being tilted in a direction of the coating source.

10. A system for coating functional surfaces of symmetrically serrated components, the system comprising:
a coating source emitting coating material as electrically charged particles in an irradiation direction toward the component, a relative rotation occurring between the component and the coating source; and
a shield operatively arranged between the component and the coating source transverse to the irradiation direction, said shield shielding the component from a coating beam in a contour area of the component with a functional surface orientation inclined flatly with respect to the irradiation direction.

11. The system according to claim 10, wherein the component is a toothed gear having tooth flanks.

12. The system according to claim 10, wherein the relative rotation between the component and the coating source is non-uniform with longer dwell times occurring in a rotational position of the functional surfaces set steeply with respect to the irradiation direction.

13. The system according to claim 10, wherein the shield is operatively configured to extend beyond one boundary of the contour area of the component in order to completely shade the component in a half-sided manner, whereby one-sided functional surface coating of the component occurs.

14. The system according to claim 12, wherein the shield is operatively configured to extend beyond one boundary of the contour area of the component in order to completely shade the component in a half-sided manner, whereby one-sided functional surface coating of the component occurs.

15. The system according to claim 10, further comprising:
at least one of a magnetic and electric field generator arranged in a beam path of the coating beam.

16. The system according to claim 15, wherein the at least one magnetic and electric field generator is operatively configured to focus the coating beam.

17. The system according to claim 10, wherein the component is a bevel gear, the bevel gear being rotated about a bevel gear axis that is tilted in a direction of the coating source.
